(19) United States
(12) Patent Application Publication
(10) Pub. No.: US 2021/0262742 A1
(43) Pub. Date: Aug. 26, 2021

(54) HEAT-SHIELDING DEVICE, IN PARTICULAR A HEAT-SHIELDING DEVICE THAT IS ADAPTABLE TO LOCALLY DIFFERING HEAT INPUTS PER UNIT AREA

(71) Applicant: ElringKlinger AG, Dettingen/Erms (DE)

(72) Inventors: Thrivikraman RANGANATHAN, Nürnberg (DE); Andreas HUBERT, Teising (DE); Peter SCHÖLZEL, Happurg (DE)

(21) Appl. No.: 17/254,180

(22) PCT Filed: Apr. 8, 2019
(86) PCT No.: PCT/EP2019/058825

§ 371 Date: Dec. 18, 2020

(30) Foreign Application Priority Data
Jul. 10, 2018 (DE) 10 2018 116 682.6

(51) Int. Cl. F28F 3/06

(52) U.S. Cl. CPC F28F 3/06

(57) ABSTRACT

A heat-shielding device with at least one flat shielding layer, the heat-shielding device being equipped and embodied to be suitable for shielding a protected component or region from the heat of a heat source wherein a passive cooling module is connected to the shielding layer in a thermally conductive fashion in at least one area of the at least one shielding layer that is subjected to a high thermal load.

### FIELD OF THE INVENTION

The invention relates to a heat-shielding device, in particular a heat-shielding device that is adaptable to locally differing heat inputs per unit area.

### BACKGROUND OF THE INVENTION

A heat shield of this generic type is known from DE 20 2011 106 603 U1. In practical use, heat shields of this type are thermally loaded in a non-uniform way across their surface so that there are areas with a higher or high thermal load and areas with a lower or low thermal load. In order to be able to design such a heat shield in a durable way, it is necessary to design the entire heat shield, e.g. in terms of its material thickness and/or its material, in accordance with the maximum thermal load.

This likewise entails high costs since the entire heat shield may have to be produced from a more expensive semi-finished product or material in order, for example, to embody a relatively small, highly loaded region (small, highly loaded area) in a sufficiently rugged way.

Such a heat shield according to the prior art is depicted in a very simplified way in FIG. 1. A heat source 1 is covered by a shielding layer 2 of a heat-shielding device 100 so that a region 3 to be shielded receives a lower heat input. The region 3 is loaded only by radiated heat 4, which penetrates the shielding layer 2 and is in turn radiated by the shielding layer 2.

In such a device according to the prior art, an area 5 that is subjected to a high thermal load can require a particular wall thickness of the shielding layer 2 or can require a material that is able to withstand a higher thermal load.

Both result in higher costs and should be avoided.

The object of the invention is to avoid the disadvantages of the prior art and in the individual case, to disclose a heat-shielding device that is adaptable to local heat input conditions. In particular, the heat-shielding device according to the invention should be adaptable or be adapted to a heat input that is not uniform (in terms of the area).

### SUMMARY OF THE INVENTION

A heat-shielding device according to the invention has at least one flat shielding layer; the heat-shielding device is equipped and embodied to be suitable for shielding a protected component or region from the heat of a heat source; and in at least one area of the at least one shielding layer that is subjected to a high thermal load, a passive cooling module is connected to the shielding layer in a thermally conductive fashion.

This solution makes it possible to produce a local thermal relief of an area that is subjected to a high thermal load. A material thickening or a selection of a more thermally resistant material is not required.

In a particular embodiment of the invention, the passive cooling module comprises a plurality of cooling fins and/or cooling rods and a base plate, it being possible for the base plate to be connected to the shielding layer. Such a cooling module can be produced in a simple way and a plurality of them can be attached to the shielding layer, e.g. next to one another, in tile-like fashion.

In another embodiment of the invention, the base plate is thin-walled, flexible, and/or pliable, which assures that the cooling module can be easily adapted to a topography of the shielding layer.

In another preferred embodiment, when cooling rods are used, the cooling module with the flexible and/or pliable base plate is flexible and/or pliable around more than one bending axis and can therefore be easily adapted to a topography of the shielding layer.

It is also advantageous that in the region of the base plate, the cooling module has fasteners for fastening the cooling module to the shielding layer.

### BRIEF DESCRIPTION OF THE DRAWINGS

The invention will be explained in greater detail below by way of example based on the drawings. In the drawings:

FIG. 1: shows a schematic cross-section through a shielding device according to the prior art;

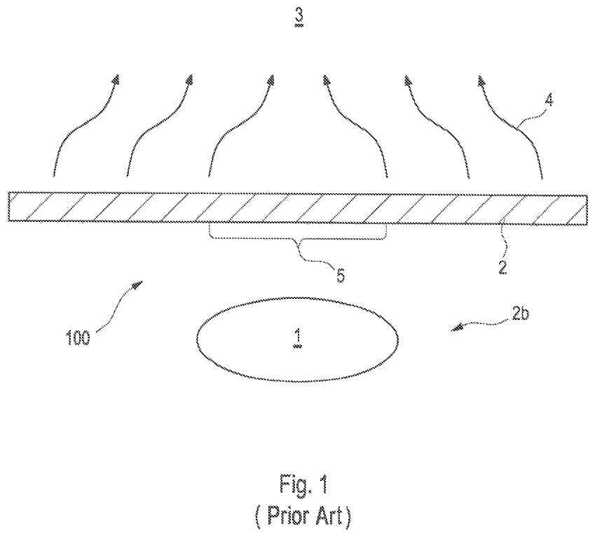

FIG. 2: shows a schematic cross-section through a shielding device according to the invention.

### DETAILED DESCRIPTION OF THE PREFERRED EMBODIMENTS

A heat-shielding device 100 according to the invention has at least one shielding layer 2, which in a known way, can be embodied of a single layer or of multiple layers. Usually, the at least one shielding layer is composed of metallic material. It is also possible, however, to use plastic/ceramic/woven fiber cloth or other materials that have proven useful for heat shielding.

A heat source 1 radiates heat onto the shielding layer 2. A region that is situated closest to the heat source 1 is an area 5 that is subjected to a high thermal load since in this region, heat from the heat source 1 is input into the shielding layer 2 with maximum area loading.

In order to reduce the temperature load/heat load of the highly loaded area 5, the invention provides a passive cooling module 200, which is positioned at least in the region of the highly loaded area 5 on the side of the shielding layer 2 oriented away from the heat source. The cooling module 200 has a base plate 201 and radiating elements (e.g. cooling fins or cooling rods 202). The cooling fins or cooling rods 202 are connected to the base plate 201 in a thermally conductive fashion. The cooling module can be a cast body or can also be assembled from individual parts (base plate 201 and cooling fins/cooling rods 202). The base plate 201 of the cooling module 200 is suitably affixed to the shielding layer 2, for example by means of screws or rivets 203, so that a heat transmission from the shielding layer 2 to the base plate 201 can take place.

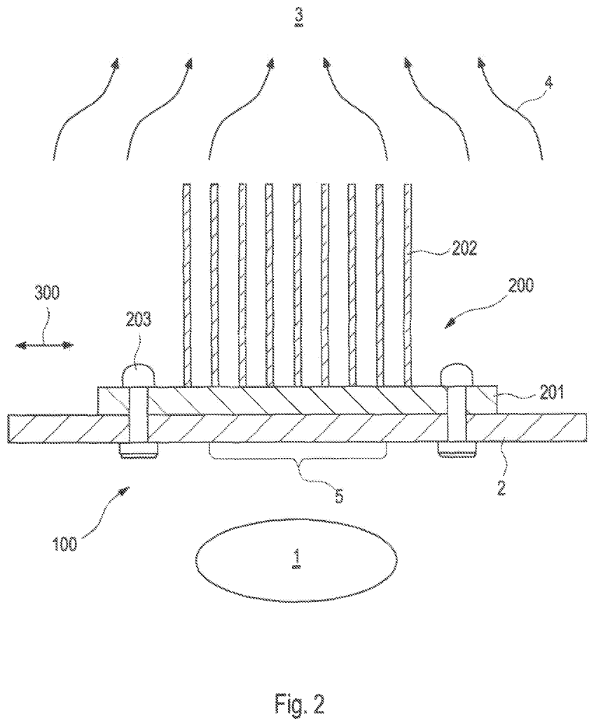

The base plate 201 is preferably made of a flexible/pliable material, e.g. in the form of a thin sheet, which has a sheet thickness of up to 0.2 mm or 0.3 mm, for example. With the use of cooling fins 202 that extend perpendicular to the plane of the drawing in the view shown in FIG. 2, such a base plate can achieve a flexibility around an axis perpendicular to the plane of the drawing in FIG. 2 and can thus be adapted (in one-dimensional fashion) to a possible topography of the shielding layer 2.

If the cooling elements are embodied as cooling rods, then a flexible, supple, and pliable base plate 201 can be used to produce a cooling module in the form of a “cooling hedgehog” that can be adapted to a topography of the shielding layer 2 around an axis 300 (see FIG. 2) and around an axis perpendicular or at an angle to the plane of the drawing in FIG. 2. A base plate 201 of this kind can, for example, also be made of a plastic material with good thermal conductivity, for example one that contains metal. Woven materials with good thermal conductivity are also suitable, for example a metal wool plate, a tangled wire, or a wire knit, in which the cooling fins/cooling rods 202 are anchored in a thermally conductive fashion.

In order to explain the term “cooling module (200),” it should be clarified that even a single cooling fin 202 or a single cooling rod 202 alone can constitute a cooling module as defined by the invention. The base plate 101, on which a plurality of cooling fins/cooling rods 202 can be positioned, essentially functions as a simplified connector for mounting a plurality of cooling fins/cooling rods 202 on the shielding layer 2. The base plate 201 is thus not a mandatory component of a cooling module 200.

The invention makes it possible, in a simple and inexpensive way, to relieve the thermal loading of an area of a heat-shielding device that is subjected to a high thermal load and to thus enable an inexpensive selection of semi-finished products/materials for embodying a heat-shielding device. This therefore makes it possible, through a local reduction of the thermal loading of the heat shielding layer, to ensure an on the whole inexpensive embodiment of a heat-shielding device.

1. A heat-shielding device suitable for shielding a protected component or region from heat of a heat source, the heat-shielding device comprising:
at least one flat shielding layer; and
a passive cooling module is connected to the shielding layer in a thermally conductive fashion in at least one area of the at least one shielding layer that is subjected to a high thermal load.

2. The heat-shielding device according to claim 1, wherein the passive cooling module comprises at least one cooling fin and/or cooling rod and a base plate that is connectable to the shielding layer.

3. The heat-shielding device according to claim 2, wherein the base plate is thin-walled, flexible, and/or pliable.

4. The heat-shielding device according to claim 2, wherein when the passive cooling module comprises the at least one cooling rod, the base plate is flexible and/or pliable, and the cooling module is flexible and/or pliable around more than one bending axis and is adaptable to a topography of the shielding layer in a region of a highly loaded area.

5. The heat-shielding device according to claim 2, wherein in a region of the base plate, the cooling module has fasteners for fastening the cooling module to the shielding layer.
